(19) United States
(12) Patent Application Publication
(10) Pub. No.: US 2025/0138057 A1
(43) Pub. Date: May 1, 2025

(54) CIRCUIT TESTING DEVICE

(71) Applicants: Richard Martinez, Rio Rico, AZ (US); Yezenia Portillo, Rio Rico, AZ (US)

(72) Inventors: Richard Martinez, Rio Rico, AZ (US); Yezenia Portillo, Rio Rico, AZ (US)

(21) Appl. No.: 18/383,964

(22) Filed: Oct. 26, 2023

(51) Int. Cl. G01R 19/165; G01R 1/067; G01R 19/15; G01R 19/155

(52) U.S. Cl. CPC G01R 19/16561; G01R 1/0675; G01R 19/15; G01R 19/155

(57) ABSTRACT

A circuit testing device for maintaining contact between the device and a ground source includes a housing having an interior space. A probe is mounted to the housing. The probe includes a circuit tip and a bulb end. The probe extends through the housing so the circuit tip is spaced apart from the housing and the bulb end is within the interior space. A lightbulb positioned within the interior space physically contacts the bulb end and is visible through the housing. A spring is positioned in the interior space and is electrically coupled to the lightbulb. The device includes a wire having a housing end and a magnet end. The housing end is attached to the spring. A magnet coupled to the magnet end can attach to a metallic surface. The probe, spring, wire, and magnet complete an electrical circuit between the positive terminal and ground source, powering the lightbulb.

### CROSS-REFERENCE TO RELATED APPLICATIONS

Not Applicable

### STATEMENT REGARDING FEDERALLY SPONSORED RESEARCH OR DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A COMPACT DISC OR AS A TEXT FILE VIA THE OFFICE ELECTRONIC FILING SYSTEM

Not Applicable

### STATEMENT REGARDING PRIOR DISCLOSURES BY THE INVENTOR OR JOINT INVENTOR

Not Applicable

### BACKGROUND OF THE INVENTION

### (1) Field of the Invention

The disclosure relates to electrical circuit testing devices and more particularly pertains to a new electrical circuit testing devices for maintaining stable contact between the circuit testing device and a negative or ground terminal, particularly while the circuit testing device is in use.

### (2) Description of Related Art Including Information Disclosed Under 37 CFR 1.97 and 1.98

The prior art relates to electrical circuit testing devices. Electrical circuit testing devices are used in a wide range of troubleshooting processes for determining if an adequate electrical current is available or flowing through a positive terminal. These devices are also used to test continuity across fuses and other circuits. Prior art circuit testing devices typically include alligator-style clips that removably couple with a negative terminal or ground source. Such alligator-style clips are difficult to use because the clips can be tough to attach to the negative terminal, particularly when the terminal has a rounded shape or is too large to fit within the mouth of the clip. These spring-tensioned clips often slip or fall off of the negative terminal in the middle of a troubleshooting or testing process. Such interruptions to the workflow can be aggravating and time-consuming. Thus, there is a need in the art for a circuit testing device that does not rely on clips to maintain the connection between the negative or ground terminal and the circuit testing device.

### BRIEF SUMMARY OF THE INVENTION

An embodiment of the disclosure meets the needs presented above by generally comprising a housing having a first wall, a second wall, and a peripheral wall extending between the first wall and the second wall to define an interior space. A probe is mounted to the housing. The probe generally includes a circuit tip and a bulb end. The probe extends through the first wall wherein the circuit tip is positioned spaced from the first wall and the bulb end is positioned in the interior space. The probe is electrically conductive. A lightbulb is positioned within the interior space. The lightbulb physically contacts the bulb end and is visible through the housing. A spring is positioned in the interior space and is electrically coupled to the lightbulb. The spring is electrically conductive. The embodiment further comprises a wire having a housing end and a magnet end. The housing end is attached to the spring. The wire extends through the second wall and is electrically conductive. A magnet is coupled to the magnet end, the magnet is configured for magnetic coupling to any ground terminal, such as the metallic surface of a car battery. The lightbulb emits light when the magnet is magnetically coupled to the metallic surface at a negative terminal and the circuit tip is contacting a positive terminal thereby closing an electric circuit. The probe, the spring, the wire, and the magnet complete the electrical circuit between the positive terminal and the negative terminal thereby allowing an electrical current to flow between the positive terminal and the negative terminal to energize the lightbulb, causing the lightbulb to emit light.

There has thus been outlined, rather broadly, the more important features of the disclosure in order that the detailed description thereof that follows may be better understood, and in order that the present contribution to the art may be better appreciated. There are additional features of the disclosure that will be described hereinafter, and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF SEVERAL VIEWS OF THE DRAWING(S)

The disclosure will be better understood and objects other than those set forth above will become apparent when consideration is given to the following detailed description thereof. Such description makes reference to the annexed drawings wherein:

FIG. 1 is an isometric view of a circuit testing device according to an embodiment of the disclosure.

FIG. 2 is a front view of an embodiment of the disclosure.

FIG. 3 is a cross-sectional view of an embodiment of the disclosure.

FIG. 4 is a cross-sectional view of an embodiment of the disclosure.

FIG. 5 is an in-use view of an embodiment of the disclosure.

### DETAILED DESCRIPTION OF THE INVENTION

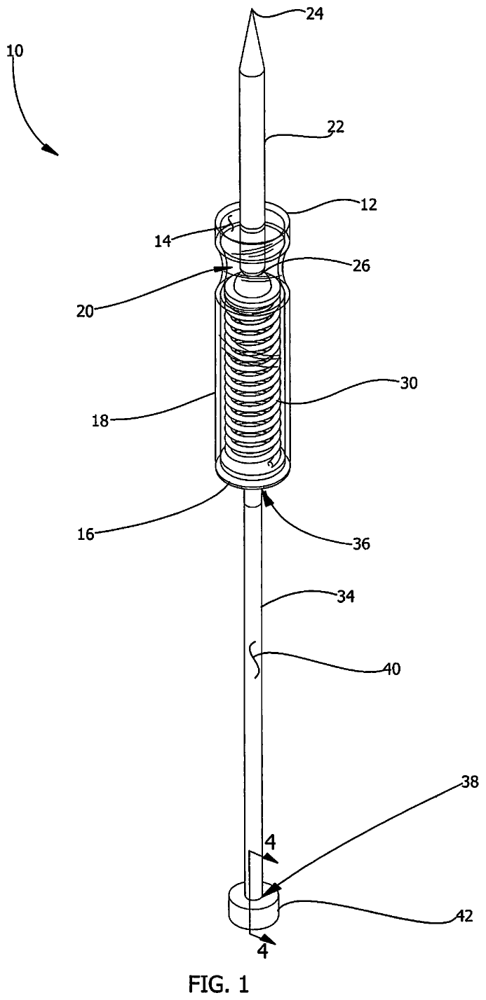

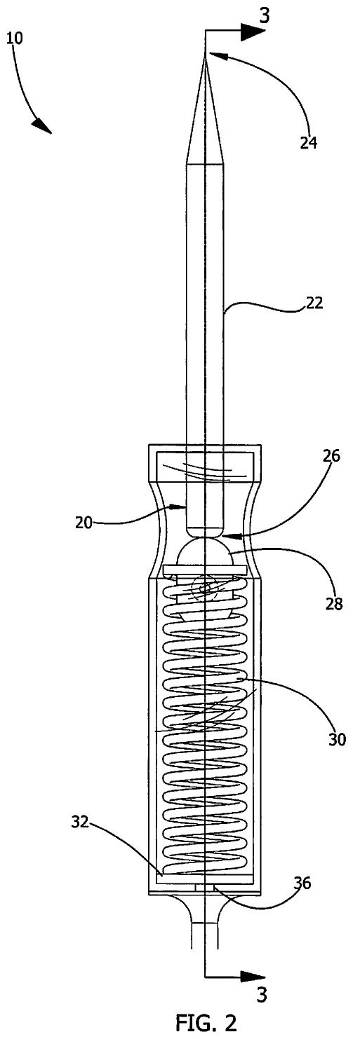

With reference now to the drawings, and in particular to FIGS. 1 through 5 thereof, a new electrical circuit testing devices embodying the principles and concepts of an embodiment of the disclosure and generally designated by the reference numeral 10 will be described.

As best illustrated in FIGS. 1 through 5, the circuit testing device 10 generally comprises a housing 12 having a first wall 14, a second wall 16, and a peripheral wall 18 extending between the first wall 14 and the second wall 16 to define an interior space 20. The housing 12 is generally dimensioned to be easily held in a user's hand. For example, the housing 12 may be substantially the shape and size of a screwdriver handle.

A probe 22 is mounted to the housing 12. The probe 22 has a circuit tip 24 and a bulb end 26. The probe 22 extends through the first wall 14 wherein the circuit tip 24 is positioned spaced from the first wall 14 and the bulb end 26 is positioned in the interior space 20. The circuit tip 24 may be pointed. The probe 22 is electrically conductive. For example, the probe 22 may be formed of an electrically conductive material such as steel alloy or other suitable material. The probe 22 is designed for connection with wires and contacts in an electrical circuit. The probe 22 is generally dimensioned to be easily held and manipulated in a user's hand, preferably without requiring two-handed use. Accordingly, the probe 22 may be substantially the shape and size of a screwdriver shank.

A lightbulb 28 is mounted to the housing 12 and positioned within the interior space 20. For example, the lightbulb 28 may comprise a light emitting diode or another suitable light source. The lightbulb 28 physically contacts the bulb end 26. The lightbulb 28 is generally visible through the housing 12. Accordingly, at least part of the housing 12 may be composed of a material that is sufficiently transparent so that the lightbulb 28 is visible when the circuit testing device 10 is in operation. For example, the housing 12 may be made completely out of a transparent or translucent material such as plastic. Alternatively, only a portion of the housing 12 covering the lightbulb 28 may be transparent or translucent.

A spring 30 is positioned in the interior space 20. The spring 30 is electrically coupled to the lightbulb 28. The spring 30 is electrically conductive and may extend between the lightbulb 28 and the second wall 16. The spring 30 may be configured to increase a resistance of an electrical current when the electrical current flows through the spring 30. For example, the spring 30 may provide an electrical resistance which impedes the flow of current through the electrical circuit.

In some embodiments, a plate 32 is mounted to the second wall 16 within the interior space 20. The plate 32 is electrically coupled to the spring 30 and is electrically conductive whereby the electrical current flows through the plate 32.

The circuit testing device 10 further comprises a wire 34 having a housing end 36 and a magnet end 38. The housing end 36 may be attached to the plate 32 or directly to the spring 30 within the housing 12. The wire 34 extends through the second wall 16. The wire 34 is electrically conductive whereby the electrical current flows through the wire. In embodiments, the wire 34 may be straight whereby the wire maintains the resistance of the electrical current when the electrical current flows through the wire.

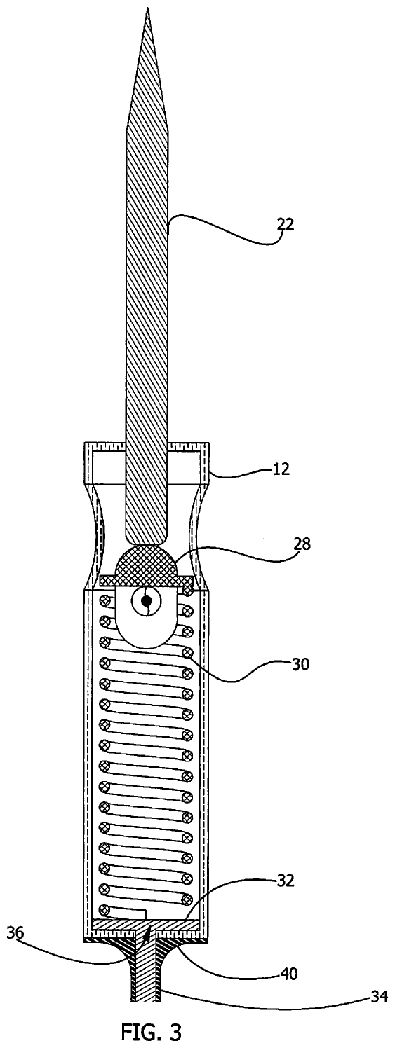

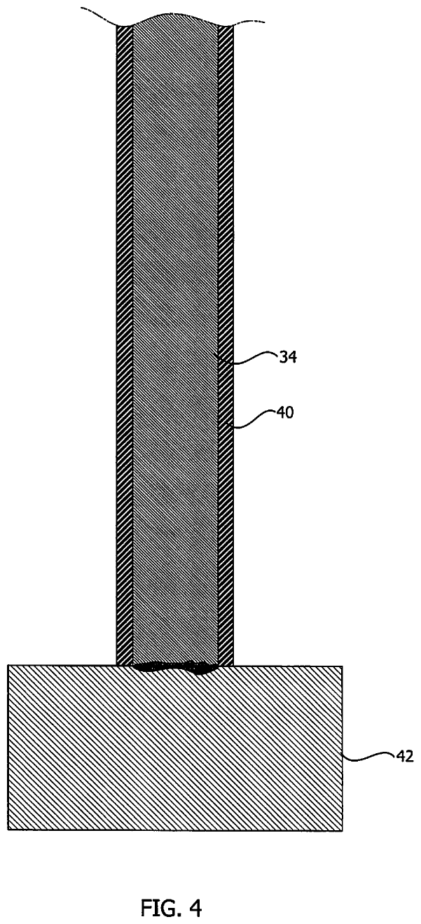

In embodiments, an insulation 40 may cover the wire 34. The insulation 40 prevents conduction of electricity along the wire 34 where the insulation 40 is covering the wire 34. For example, in the embodiment shown in FIGS. 3 and 4, the external surface of the wire 34 is coated in the insulation 40 thereby preventing conduction or flow of electricity outwardly through the external surface and ensuring electricity only flows into or out of the wire 34 through the housing end 36 or the magnet end 38.

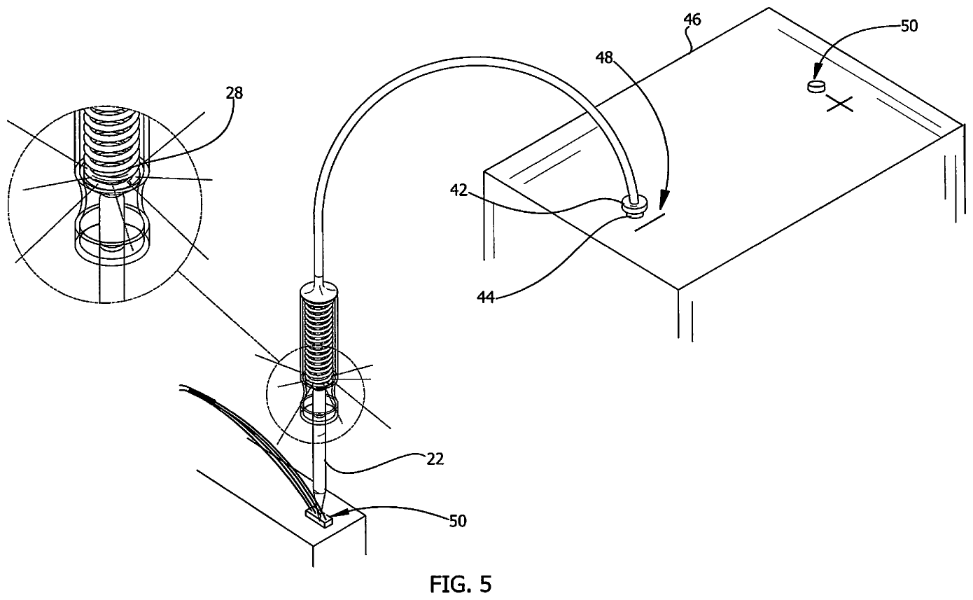

A magnet 42 is coupled to the magnet end 38. For example, the magnet 42 may be soldered to the magnet end 38. The magnet 42 is configured for magnetic coupling to a metallic surface 44. The metallic surface 44 may be on any ground source 48 available, for example a metallic surface 44 of a negative terminal 48 on a battery 46 as shown in FIG. 5. The magnet 42 is electrically conductive whereby the electrical current flows through the magnet 42. For example, the magnet 42 may be enclosed in a metal or otherwise electrically conductive housing which is connected to the wire 34.

Because the magnet 42 can magnetically couple to the metallic surface 44 of the battery 46, the magnet 42 will retain connection with the battery 46 while the circuit testing device 10 is in use. The magnet 42 may also couple to any other available metallic or magnetically active ground source. This is an advantage over prior art devices which use clips to connect with the negative terminal 48 or otherwise ground the electrical current because of the difficulty associated with retaining the connection of such prior-art clips with the negative terminal 48. For example, alligator-style clips often slip or slide off of the negative terminal 48, interrupting workflow while the circuit testing device 10 is in use. Moreover, because the magnet 42 is configured for magnetic coupling to a metallic surface 44, the magnet 42 can magnetically couple to other metallic surfaces, such as a wall of a toolbox, making the circuit testing device 10 easier for a user to find amongst their tools. The magnet 42 can accordingly also magnetically couple to a ground source 48 that has a metallic surface, such as a grounded metallic surface on a car or other device on which the circuit testing device 10 is being used.

The lightbulb 28 emits light when the magnet 42 is magnetically coupled to the metallic surface 44 at a negative terminal 48 and the circuit tip 24 is contacting a positive terminal 50 thereby closing an electric circuit. In other embodiments, the lightbulb 28 emits light when the magnet 42 is magnetically coupled to another ground source 48 and the circuit tip 24 is contacting the positive terminal 50 thereby closing the electric circuit. The negative terminal 48 grounds the electric circuit and the positive terminal 50 provides the electrical current. In some embodiments, the electrical current is an alternating current, while in other embodiments other types of current may be used. In some embodiments, such as those designed for use in testing car batteries, the electrical current comprises between 6.0 volts and 16.0 volts. Other embodiments may be designed for different voltages of electrical current.

The probe 22, the spring 30, the wire 34, and the magnet 42 complete the electrical circuit between the positive terminal 50 and the negative terminal 48, or another ground source 48, thereby allowing the electrical current to flow between the positive terminal 50 and the negative terminal 48 to power the lightbulb 28 and to cause the lightbulb 28 to emit light.

In use, a user may magnetically couple the magnet to any ground source 48, such as the metallic surface 44 of the battery 46 as shown in FIG. 5, or another metallic surface, for example a grounded metallic surface of a car. The user can then touch the circuit tip 24 of the probe 22 to a wire or other positive terminal 50 that the user desires to troubleshoot or test for electrical current. If the electrical current is present, the electrical circuit between the positive 50 and negative 48 terminals will be completed and closed by the circuit testing device 10. The flow of electricity through the probe 22, the spring 30, wire 34, and the magnet 42 will power or energize the lightbulb 28 such that the lightbulb 28 lights up and emits light. The magnet 42 will remain magnetically coupled with the metallic grounding surface 44 until removed by the user thereby reducing interruptions in workflow over prior art devices.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure. In this patent document, the word “comprising” is used in its non-limiting sense to mean that items following the word are included, but items not specifically mentioned are not excluded. A reference to an element by the indefinite article “a” does not exclude the possibility that more than one of the elements is present, unless the context clearly requires that there be only one of the elements.

I claim:

1. A circuit tester comprising:
a housing having a first wall, a second wall, and a peripheral wall extending between the first wall and the second wall to define an interior space;
a probe being mounted to the housing, the probe having a circuit tip and a bulb end, the probe extending through the first wall wherein the circuit tip is positioned spaced from the first wall and the bulb end is positioned in the interior space, the probe being electrically conductive;
a lightbulb being positioned within the interior space, the lightbulb physically contacting the bulb end, the lightbulb being visible through the housing;
a spring being positioned in the interior space, the spring being electrically coupled to the lightbulb, the spring being electrically conductive;
a wire having a housing end and a magnet end, the housing end being attached to the spring, the wire extending through the second wall, the wire being electrically conductive;
a magnet being coupled to the magnet end, the magnet being configured for magnetic coupling to a metallic surface;
wherein the lightbulb emits light when the magnet is magnetically coupled to the metallic surface at a negative terminal and the circuit tip is contacting a positive terminal thereby closing an electric circuit; and
wherein the probe, the spring, the wire, and the magnet complete the electrical circuit between the positive terminal and the negative terminal thereby allowing an electrical current to flow between the positive terminal and the negative terminal to energize the lightbulb causing the lightbulb to emit light.

2. The circuit tester of claim 1, wherein the negative terminal grounds the electric circuit and wherein the positive terminal provides the electrical current.

3. The circuit tester of claim 1, wherein the electrical current is between 6.0 volts and 16.0 volts.

4. The circuit tester of claim 1, the electrical current further comprising an alternating current.

5. The circuit tester of claim 1, wherein the magnet is electrically conductive whereby the electrical current flows through the magnet.

6. The circuit tester of claim 1, the housing further comprising a transparent plastic material.

7. The circuit tester of claim 1, wherein the circuit tip is pointed.

8. The circuit tester of claim 1, the lightbulb further comprising a light emitting diode.

9. The circuit tester of claim 1, wherein the spring extends between the lightbulb and the second wall.

10. The circuit tester of claim 1, wherein the spring is configured to increase a resistance of the electrical current when the electrical current is flowing through the spring.

11. The circuit tester of claim 10, wherein the wire is straight thereby maintaining the resistance of the electrical current when the electrical current flows through the wire.

12. The circuit tester of claim 11, further comprising a plate being mounted to the second wall within the interior space, the plate being electrically coupled to the spring and the wire, the plate being electrically conductive whereby the electrical current flows through the plate between the spring and the wire.

13. The circuit tester of claim 1, further comprising an insulation covering the wire, the insulation preventing conduction of electricity along the wire where the insulation is covering the wire.

14. A circuit tester comprising:
a housing having a first wall, a second wall, and a peripheral wall extending between the first wall and the second wall to define an interior space, the housing comprising a transparent plastic material;
a probe being mounted to the housing, the probe having a circuit tip and a bulb end, the probe extending through the first wall wherein the circuit tip is positioned spaced from the first wall and the bulb end is positioned in the interior space, the circuit tip being pointed, the probe being electrically conductive;
a lightbulb being mounted to the housing, the lightbulb being positioned within the interior space, the lightbulb physically contacting the bulb end, the lightbulb being visible through the housing, the lightbulb comprising a light emitting diode;
a spring being positioned in the interior space, the spring being electrically coupled to the lightbulb, the spring being electrically conductive, the spring extending between the lightbulb and the second wall, the spring being configured to increase a resistance of an electrical current when the electrical current flows through the spring;
a plate being mounted to the second wall within the interior space, the plate being electrically coupled to the spring, the plate being electrically conductive whereby the electrical current flows through the plate;
a wire having a housing end and a magnet end, the housing end being attached to the plate, the wire extending through the second wall, the wire being electrically conductive whereby the electrical current flows through the wire, the wire being straight whereby the wire maintains the resistance of the electrical current when the electrical current flows through the wire;
an insulation covering the wire, the insulation preventing conduction of electricity along the wire where the insulation is covering the wire;
a magnet being soldered to the magnet end, the magnet being configured for magnetic coupling to a metallic surface, the magnet being electrically conductive whereby the electrical current flows through the magnet;
wherein the lightbulb emits light when the magnet is magnetically coupled to the metallic surface at a ground source and the circuit tip is contacting a positive terminal thereby closing an electric circuit, the negative terminal grounding the electric circuit, the positive terminal providing the electrical current, the electrical current being an alternating current, the electrical current comprising between 6.0 and 12.0.0 volts; and
wherein the probe, the spring, the wire, and the magnet complete the electrical circuit between the positive terminal and the negative terminal thereby allowing the electrical current to flow between the positive terminal and the ground source to power the lightbulb causing the lightbulb to emit light.
